(19) United States
(12) Patent Application Publication
(10) Pub. No.: US 2018/0179629 A1
(43) Pub. Date: Jun. 28, 2018

(54) Apparatus and Methods for High Volume Production of Graphene and Carbon Nanotubes on Large-Sized Thin Foils

(71) Applicant: Vladimir MANCEVSKI, Austin, TX (US)

(72) Inventor: Vladimir Mancevski, Austin, TX (US)

(21) Appl. No.: 15/738,938

(22) PCT Filed: Jun. 24, 2016
(86) PCT No.: PCT/US2016/039217

§ 371 Date: Dec. 21, 2017

Related U.S. Application Data
(60) Provisional application No. 62/184,806, filed on Jun. 25, 2015.

(51) Int. Cl. C23C 16/458; C23C 16/26; C23C 16/455

(52) U.S. Cl. CPC C23C 16/4583; C23C 16/45546; C23C 16/26

(57) ABSTRACT

Apparatus and methods for growing nanomaterials in high volume production on large-sized thin metal foils that includes one or more metal foils physically separated by one or more gas permeable separators that are stacked or rolled with high density packing, placed in a gas deposition chamber, and exposed to a gas deposition process. The gas permeable separator(s) allows gases and heat from the gas deposition process to form the nanomaterials on both sides of the foil(s) stacked or rolled with the separator(s). Nanomaterials, such as graphene, carbon nanotubes, graphene-carbon nanotube hybrid materials, are some of the nanomaterials that may be grown. The nanomaterials may be used in anodes and cathodes for batteries, supercapacitors, sensors, and other devices.

### CROSS-REFERENCE TO RELATED APPLICATIONS

This application is a National Stage of International Application No. PCT/US2016/039217, filed Jun. 24, 2016, which claims the benefit of U.S. Provisional Application No. 62/184,806, filed Jun. 25, 2015.

### TECHNICAL FIELD

The present invention is generally related to apparatus and methods for high volume production of films on large-sized thin metal foils, and, in particular, to high volume production of graphene and carbon nanotubes (CNTS) on large-sized thin foils using chemical vapor deposition (CVD) or atomic layer deposition (ALD).

### BACKGROUND OF THE INVENTION

In conventional chemical vapor deposition (CVD) and atomic layer deposition (ALD) processes, shown in FIG. 1, a single Cu or Ni foil 105 is placed on a sample carrier 107. The sample carrier is placed inside a CVD chamber 101 which is subjected to high temperatures with a heater element 100 and a flow of a mixture of gases 103. In this configuration most of the CVD chamber space 102 is not being used as the sample only uses a small fraction of the CVD chamber volume. A CVD deposition film 104 can be formed on a top side (or top surface) 108 of the sample foil 105. A back side (or back surface) 106 of the sample 105 is placed in physical contact with the carrier 107 and is not exposed completely to the gas flow 103, preventing complete and uniform film formation on the back side 106 of the sample 105. Only a single sample 105 can be processed with this approach. Examples of CVD growth include graphene grown on Cu or Ni foils, CNT grown on graphene, and CNT grown on metal foils, silicon or silicon oxide samples.

For samples that are stiff enough to be suspended, such as the wafers used in the semiconductor industry, it is common to use fixtures with rails 207, as shown in FIG. 2, where wafers 205 are loaded vertically or horizontally onto rails 207 and the fixture is loaded into a CVD chamber 201 for deposition of a thin film 204 using known thin film processes. A CVD gas flow 203 is in or out of the page of FIG. 2. In this configuration, a small fraction 208 of the wafer 205 is obscured by the rail 207 and produces a low quality film where obscured, but most of top 209 and bottom 206 sides of the wafer 205 are exposed to the gas flow 203 and heat required for the CVD process. For samples, however, where the thickness of the material is small or the sample stiffness is low, such as metal foils, this suspension approach is not ideal.

In applications where the substrate is thin or stiffness low (e.g., a metal foil), and where there is a need to have thin film deposited on both sides of the foil, the most common approach is to use a rolled substrate. FIG. 3 shows a prior art roller implementation where both a top side 309 and a bottom side 306 of a thin foil 305 are exposed to a gas flow 303 inside a CVD chamber 301. Using a roller-to-roller translating mechanism 307 allows thin film 304 to form on the top 309 and the bottom 306 sides of the single foil 305 simultaneously. Only the single foil 305, however, can be processed between the rollers and the process speed depends on the speed of the rollers that translate the sample in the process chamber with constant speed. If the process speed cannot be increased, longer CVD chambers are required and a roller-to-roller distance 308 has to increase. In this configuration, most of CVD chamber space 302 is not being used.

For applications where the substrate is thin and not stiff and where there is a need to have a thin film deposited on both sides of a foil, an alternate approach is to roll up a foil substrate 405 and insert it into the CVD chamber 401 in the form of a tube oven, as schematically shown in FIG. 4. In this approach, the substrate 405 needs to be stiff enough to hold a rolled up shape, but it may be difficult to control a gap 406 between rolled portions of the sample 405. If the foil 405 collapses and touches itself at a collapsed point 407, the CVD growth will be disrupted and non-continuous.

### SUMMARY OF THE INVENTION

Embodiments of the invention allow nanomaterials to be grown in a gas deposition process on one or more foils using one or more gas permeable separators. The gas deposition process may be CVD, but it may instead be ALD. Each separate gas permeable separator may be placed in physical contact with one or at most two of the one or more foils. The one or more foils may be stacked with one or more of the gas permeable separators. For clarification, stacked means that a first gas permeable separator is physically set or placed on top of a first foil, and a second foil is physically set or placed on top of the first separator, followed by a second separator that is placed on top of the second foil, and so on, until the desired number of foils and separators are prepared. The nanomaterial may be graphene, carbon nanotubes, graphite, graphene flakes, graphene oxide, reduced graphene oxide, graphene nanoribbons, and others. The one or more foils may already have a nanomaterial grown thereon before growth of another nanomaterial thereon. The one or more gas permeable separators may each be a quartz fiber filter, have a thickness preferably of 0.38 mm to 1.0 mm, and may be flexible. The gas permeable separators preferably may have pores with a pore size of 0.1 microns to 10.0 microns.

Embodiments of the invention may instead include a foil rolled with a gas permeable separator in physical contact with the foil. Such embodiments may have a rolled foil pitch of 0.38 mm or less, such as 0.1 mm. In addition, a stack of multiple foils and separators may also be rolled together, in accordance with other embodiments of the invention. The foil(s) and gas permeable separator(s) may be rolled such that the gas permeable separator(s) is (are) compressed. The compression ratio depends on the porosity of the separator, where a higher porosity separator, having more voids, may be compressed more than a separator with lower porosity, having fewer voids.

Other embodiments of the invention may instead include a metal foam rolled upon itself such that adjacent rolled portions are physically touching, and the foam acts as both the substrate on which a nanomaterial is formed and the gas permeable separator, and where a nanomaterial may be formed anywhere on the surfaces of the foam exposed to the process gases.

### BRIEF DESCRIPTION OF THE DRAWINGS

FIG. 1 shows a prior art system for graphene growth primarily on the top side of a single Cu or Ni foil that is exposed to the gas flow in a CVD process.

FIG. 2 shows prior art samples that are suspended on rails for CVD growth.

FIG. 3 shows a prior art system that uses a roll-to-roll mechanism for allowing graphene growth on the top and bottom sides of a single foil.

FIG. 4 shows a prior art rolled foil having a spaced gap between rolled portions of the foil.

FIG. 5 shows the relation between a metal foil and a gas permeable separator, in accordance with an embodiment of the invention.

FIG. 6 shows multiple metal foils (e.g., Cu or Ni foils) stacked with and separated by gas permeable material, in accordance with an embodiment of the invention.

FIG. 7 schematically shows a CVD system that includes a CVD chamber and an exchange/cool-down chamber, in accordance with an embodiment of the invention.

FIG. 8 schematically shows the simultaneous growth of graphene on both sides (i.e., the top and bottom sides or surfaces) of multiple stacked foils (e.g., Cu or Ni foils) that are separated by gas permeable separators, in accordance with an embodiment of the invention.

FIG. 9 schematically shows the simultaneous growth of CNTs on graphene coated with a CNT catalyst on a single side (i.e., on the tops) of multiple stacked foils (e.g., Cu or Ni foils) separated by gas permeable separators, in accordance with an embodiment of the invention.

FIG. 10 schematically shows the simultaneous growth of CNTs on graphene coated with a CNT catalyst on both sides (i.e., on the top and bottom sides) of multiple stacked foils (e.g., Cu or Ni foils) separated by gas permeable separators, in accordance with an embodiment of the invention.

FIG. 11 schematically shows a rolled or spiral foil assembly with a gas permeable separator between the foil surfaces (i.e., the top and bottom sides) for CVD growth with the flow in or out of the page, in accordance with an embodiment of the invention.

FIG. 12 shows a micrograph of a gas permeable separator made of quartz fibers with 2 μm average pore size and thickness of 0.38 mm that may be used in a CVD process up to a maximum operating temperature of 1000 C, in accordance with an embodiment of the invention.

FIG. 13 shows a micrograph of a vertically aligned CNT film that was grown on top of a graphene film having a Ni foil substrate with the help of gas permeable separators, in accordance with an embodiment of the invention.

FIG. 14 shows a close-up micrograph of the vertically aligned CNT film of FIG. 13.

FIG. 15 shows a micrograph of a CNT film with bundled CNTs grown on top of a graphene film having a Ni foil substrate with the help of gas permeable separators, in accordance with an embodiment of the invention.

FIG. 16 shows a close-up micrograph of the CNT film of FIG. 15.

FIG. 17 schematically shows simultaneous compression of multiple CNT films grown on multiple stacked foils to increase the volumetric density of the films, in accordance with an embodiment of the invention.

FIG. 18 shows a roller system used to peel off a separator and compress the as-grown CNT film on a foil to form a compressed CNT film, in accordance with an embodiment of the invention.

FIG. 19 shows a micrograph of a CNT film before (left) and after (right) compression to increase the volumetric density of the CNT film, in accordance with an embodiment of the invention.

FIG. 20 schematically shows a metal foam rolled upon itself such that adjacent rolled portions of the metal foam physically touch each other, where nanomaterial may be grown anywhere on the surfaces of the metal foam exposed to process gases, in accordance with an embodiment of the invention.

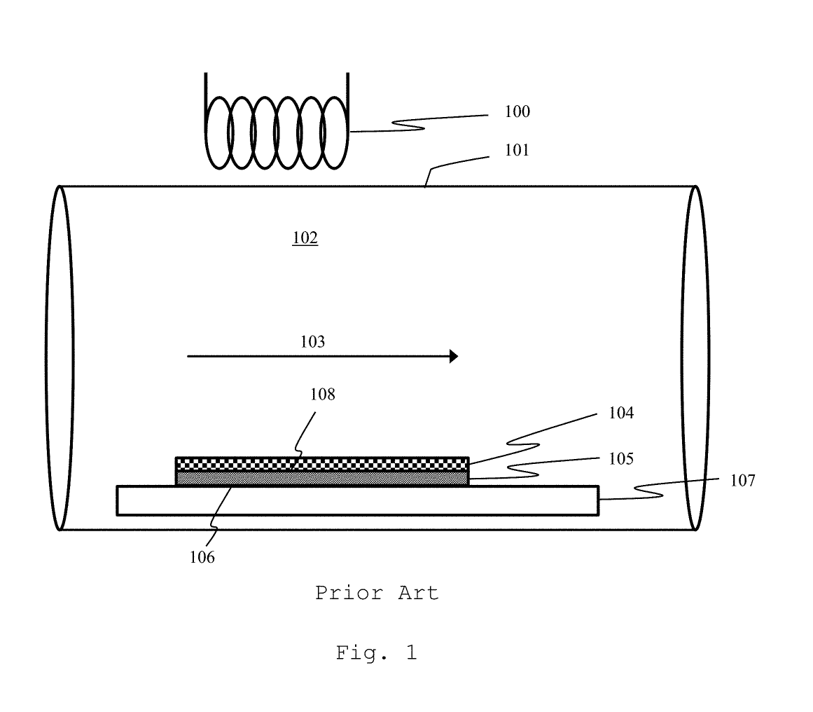

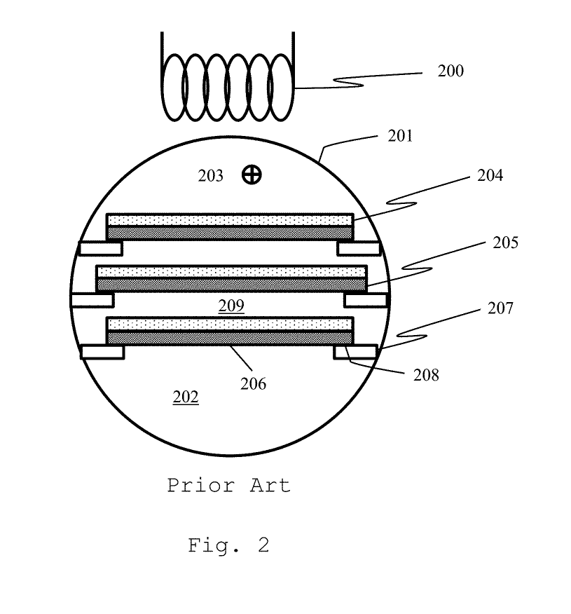

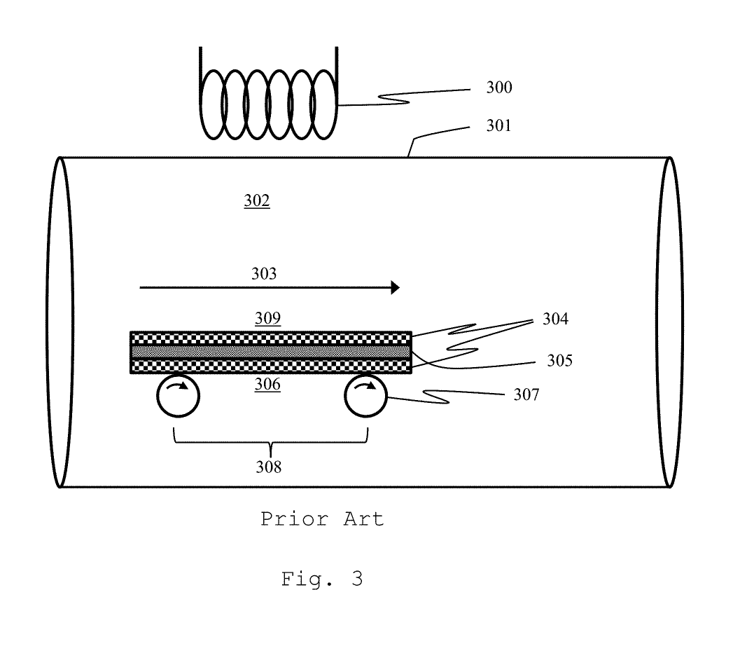

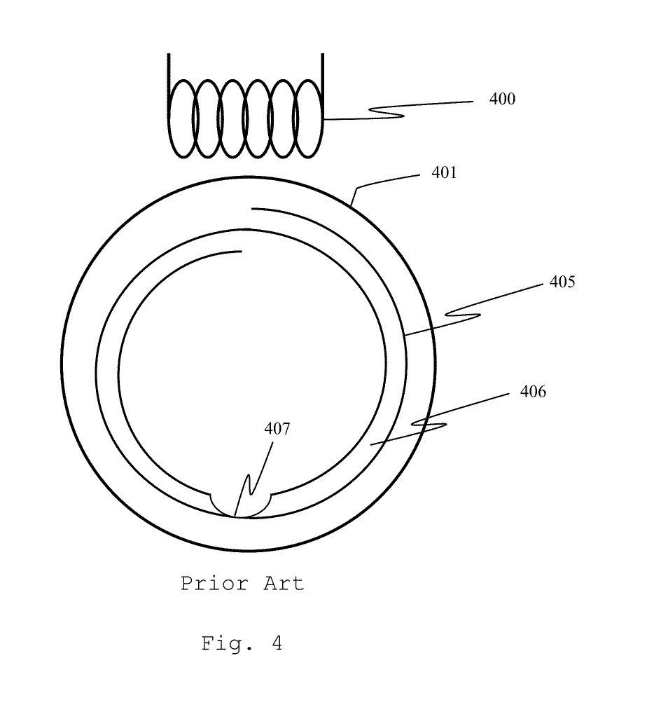

### DETAILED DESCRIPTION

This application claims the benefit of U.S. Provisional Application No. 62/184,806, filed Jun. 25, 2015, which is incorporated by reference herein in its entirety.

Apparatus and methods for deposition of a thin film on the surface(s) of large-sized metal foil(s) (also referred to as sheets) using gas deposition, such as CVD or ALD processes are described herein, in accordance with embodiments of the invention. The thin film gas deposition process is for growth of nanomaterials, nonlimiting examples of which include graphene, carbon nanotubes, hybrid nanomaterial comprising carbon nanotubes grown directly on graphene or other carbon-based nanomaterials. The apparatus for thin film deposition may include a stack of multiple sheets which are separated by gas permeable material(s), a CVD or ALD chamber in which the CVD or ALD deposition takes place, and a control system to control the process parameters, such as gas flow and temperature.

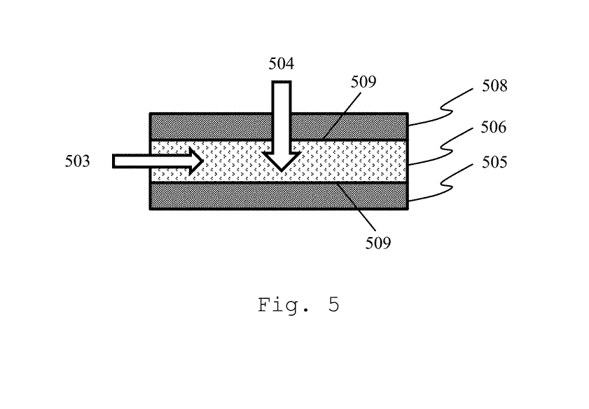

FIG. 5 schematically shows the relationship and relative positioning between the metal foil and the gas permeable separator, in accordance with an embodiment of the invention. The gas permeable separator makes physical contact with two of the foils in this embodiment. However, it may be in contact with only one foil. The role of gas permeable material separator 506 is to physically separate adjacent sheets 505 and 508 while allowing gases 503 to flow through the separator 506 to reach surfaces 509 of the sheets. Another role of the gas permeable material 506 is to allow heat 504 to transfer from the surroundings to the sheets 505 and 508. The gas permeable separator 506 should be able to operate in a temperature range from 800 C to 1000 C for growing graphene, in a range from 600 C to 900 C for growing carbon nanotubes, and in a range from 120 C to 600 C for growing other nanomaterials. The gas permeable separator 506 should generally operate in a temperature range of interest or as required by the particular desired nanomaterial film to be deposited and properties of the deposition system without significant deterioration of the porous structure of the separator material, as would be understood by a person of ordinary skill in the art. Some deterioration may be acceptable as long as it does not significantly degrade the ability of the separator to allow gas to flow and transfer heat through it. The gas flow 503 and heat 504 enable a CVD or ALD reaction to occur on a surface 509 of the sheets 505 or 508. The gas permeable separator 506 may be flexible or rigid, depending on the material and the thickness of the filter material used. A flexible separator is one that may be bent or rolled and a rigid separator is one that may not be easily bent or rolled. Examples of flexible gas permeable materials include glass, quartz, and ceramic materials in a fiber form factor, which may be packaged as filters typically used for gas or liquid filtration.

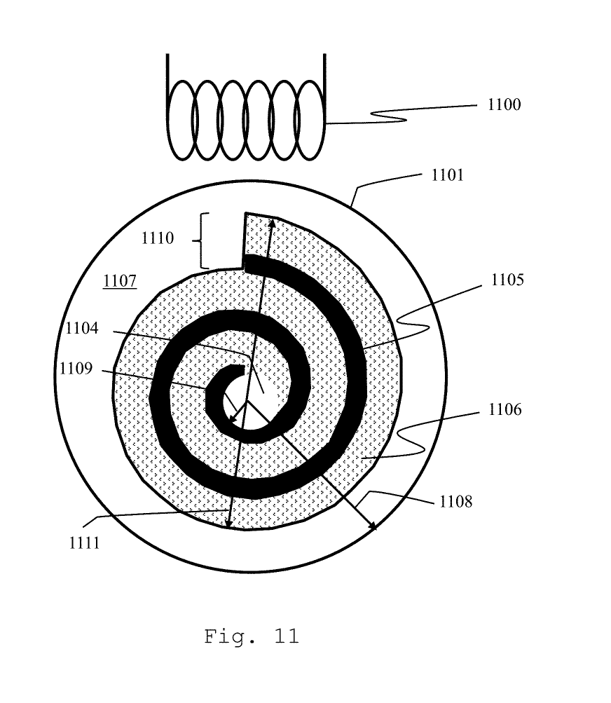

A quartz fiber filter having a thickness from 0.38 mm to 1.00 mm is an exemplary flexible gas permeable separator. Such a separator has been used for high temperature sampling of acidic gases and for air pollution analysis, and typically have a maximum operating temperature of 1000 C. Thinner quartz fiber filters are also contemplated. The typical pore size in a quartz filter is 2 μm, but pore sizes ranging from 0.1 μm to 10 μm are also contemplated. The typical diameter of a quartz fiber from a quartz filter is in the range of 0.1 to 10 μm. FIG. 12 shows a micrograph of such an exemplary filter used as a gas permeable separator. For CVD or ALD applications where the reaction temperature is less than or equal to 550 C, an exemplary borosilicate glass fiber may be used. For applications where the reaction temperature is less than or equal to 120 C, an exemplary glass fiber may be used. Another exemplary flexible gas permeable separator is quartz wool made of quartz fibers having diameters ranging from 0.1 to 30 μm, typically having a bulk form factor and not a pre-formed form factor. The quartz wool may be formed and compressed to any form factor.

A metal foam material may also be used as an exemplary gas permeable separator. Typically, Cu or Ni foam has a thickness of 1.6 mm and pores sizes in the range of 20 to 60 μm. Other exemplary metal foams include stainless steel and aluminum. A metal foam separator preferably is not used when the material of the foam is catalytic to the formation of the nanomaterial meant to be fabricated in the CVD process.

Exemplary rigid or stiff gas permeable materials include porous alumina, porous zirconia, and porous titania filters that are also used for gas or liquid filtration. Other exemplary rigid permeable separators include quartz filter disks, otherwise known as quartz sintered disks or quartz fritted disks or quartz frits. Sintered or fritted disks typically are made from fusing quartz granules together, and have an average pore size ranging from 10 to 500 μm, depending on the porosity grade of the filter.

Exemplary foil or sheet samples may be any materials suitable for CVD or ALD processes, including but not limited to, Cu and Ni foils having thicknesses ranging from 0.1 μm to 100 μm. More preferably, thin metal foils having a thickness range from 9 μm to 35 μm are suitable for these processes. Extremely thin metal foil samples that cannot easily be suspended on rails and stacked in multiple layers may be used in accordance with embodiments of the invention. For example, a 9 μm thick Cu foil tends to soften and lose stiffness when exposed to high temperatures close to 1000 C, and therefore cannot easily be suspended on rails. Yet, such a metal foil may be used in embodiments of the invention.

There is no fundamental or little limitation on the size or dimensions of the foil that the gas permeable material may support. For example, a 100 mm wide Cu foil with length of 1 to 2 m may easily be supported by a gas permeable separator with the same or similar size for stacking in multiple layers with such foils, in accordance with an embodiment of the invention. It is mainly the size of the CVD chamber that may limit the dimensions of the foil. This is true even though rail suspension generally is particularly difficult for foil samples having a width or length 10 mm or larger. And it is true even though rail-supported suspension is not generally mechanically stable, as vibration may cause adjacent foil layers to contact each other or change the gap(s) between them.

It should be noted that the foil itself may already have nanomaterial(s) deposited on it before further nanomaterial(s) is (are) deposited on it thereafter, in accordance with other embodiments of the invention. For example, a Ni foil already having graphene grown on it that is covered with a CNT catalyst material may be used to grow nanomaterial(s), such as CNTs, on the graphene.

Besides Cu and Ni foil, other materials may be used for growth of nanomaterials thereon. For example, as mentioned above, a foam, such as Cu foam or Ni foam, may be used in accordance with embodiments of the invention. Typically, Ni and Cu foams are 0.08 mm to 1.6 mm thick. The foam material may be used with additional gas permeable separator(s), such as quartz filter(s). Or the foam may be used without any gas permeable separator(s) because the foam material is itself gas permeable, having the porosity to enable gas flow and heat transfer, and function as a substrate for the growth of the nanomaterial. In this case, the samples of foam are just physically stacked on top of each other, and graphene or CNT growth may take place on the surfaces of each sample of the foam. The surface of a foam is understood to be the total surface area of the foam material that can be exposed to the process gases in the process chamber. It should be noted that the foam itself, just as for the foil, may already have nanomaterial(s) deposited on it before further nanomaterial(s) is (are) deposited on it thereafter, in accordance with other embodiments of the invention. For example, a Ni foam already having graphene grown on it that is covered with a CNT catalyst material may be used to grow nanomaterial(s), such as CNTs, on the graphene.

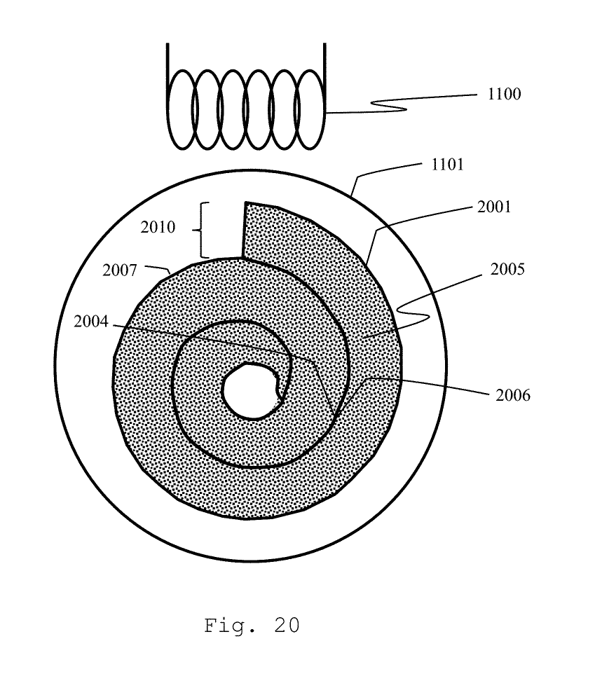

FIG. 20 schematically shows a porous metal foam 2001 rolled upon itself such that any adjacent rolled portions 2004 and 2006 of the metal foam physically touch each other, and the metal foam acts as both the substrate on which a nanomaterial is grown and the gas permeable separator, in accordance with an embodiment of the invention. In such embodiments, nanomaterial may be grown anywhere on any of surfaces (i.e., on any internal 2005 or any external surfaces 2007) of the rolled foam 2001, including on the surfaces defining any pores in the interior and on the exterior of the foam 2001, which are exposed to the process gases. In this embodiment roll pitch 2010 is the same or approximately the same as the metal foam thickness.

Other carbon-based materials that may be used as a foil on which CNTs may be grown include, but are not limited to, graphite, graphene flakes, graphene oxide, reduced graphene oxide, and graphene nanoribbons. The material of the foil may also be in the form of a thin filter morphology.

The gas permeable separator also does not need to be a single discrete continuous piece of material as long as the discrete pieces can support the foil and provide mechanical stability, in accordance with other embodiments of the invention. Moreover, the gas permeable separator or multiple separators may only be a fraction of size of the two major dimensions, i.e. length and width, of the foil supported. Exemplary embodiments include a separator that is 1/10th or 1/100th the length or width of the foil it supports. One exemplary embodiment includes three gas permeable separators per each foil stably holding each foil, although each such separator is much smaller in length or in width compared to each foil. Other exemplary embodiments include a different number of separators per each foil than three stably holding each foil. The shape of each of the multiple separators may be long rectangles positioned parallel to the axis of a tube CVD chamber or positioned perpendicular to the axis of a tube CVD chamber, or placed in any optimized position for separating the thin foils using a minimum number and position of separators, as would be understood by a person of ordinary skill in the art. The major determinant is to have the multiple separators spaced close enough to prevent the foil from touching a neighboring foil in the stack. The spacing of the discrete separators will depend on the thickness of the foil; thinner foil will require closer discrete separator spacing. For example, a 10 cm long and 9 μm thick foil may be separated by using two discrete separators that are 0.5 cm long, 1.0 cm wide, matching the width of the foil, and are spaced 5 cm apart.

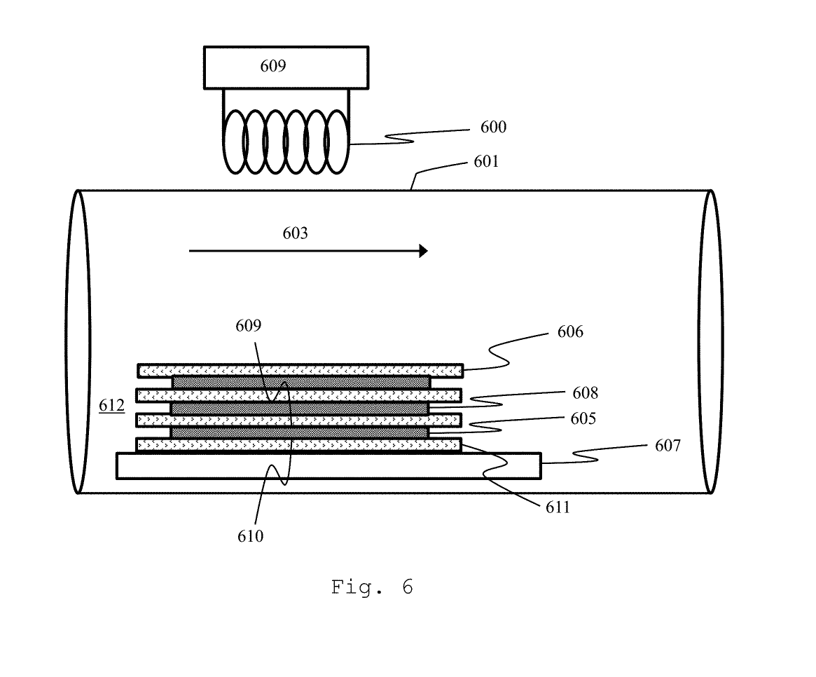

FIG. 6 schematically shows an apparatus and method for stacking of multiple Cu or Ni foils 605 separated by gas permeable material separators 606, in accordance with an embodiment of the invention. A CVD or ALD chamber 601 may be a tube oven where a heater element 600 is located outside of the tube and surrounds the tube to optimize the delivery of heat. Alternatively, a metal wall chamber may be used where the heater element 600 is located inside the chamber 601 and oriented towards the sample to optimize the delivery of heat. One example of such an apparatus includes a quartz tube having a 150 mm inside diameter (ID) and a length of 1.8 m. The quartz tube may accommodate rectangular foils having a 100 mm width and a 1.5 m length, which may be stacked vertically up to a height of 100 mm, for example, thereby using the vertical space of the tube very efficiently. For a Cu foil having a 9 μm thickness and a gas permeable separator having a 0.38 mm thickness, up to 257 layers of the Cu foil may be stacked, in accordance with an embodiment of the invention. Using a gas permeable separator having a 0.1 mm thickness would allow even more layers of Cu foil to be stacked efficiently.

Referring again to FIG. 6, both top 609 and bottom 610 sides (or surfaces) of each of the Cu or Ni foils 605 are exposed to the surrounding atmosphere through the gas permeable separators 606. A bottom separator 611 of the stack is placed on a sample carrier 607 so that a sample 612 may be easily moved and removed from a CVD chamber 601. The sample carrier 607 is placed inside the chamber 601 manually or automatically in an automated system before the chamber 601 is closed to the atmosphere in the room, as would be understood by a person of ordinary skill in the art.

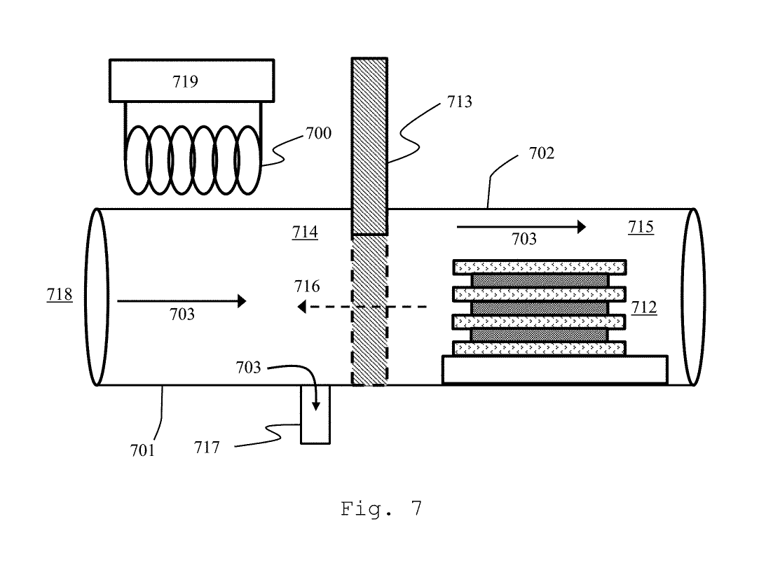

FIG. 7 schematically shows a hot main chamber 714 of a CVD or ALD system, and purge gasses 703, such as nitrogen or argon, flow through the chamber 714 while a sample 712 (e.g., stacked foil(s) and separator(s)) is inserted and held in an adjacent chamber 715 that is not heated but is purged with the same gasses 703 as the main chamber 714, in accordance with an embodiment of the invention. After a gate valve 713 is opened, the sample 712 may be inserted 716 into the main heated chamber 714. During the CVD or ALD process the gate valve 713 may remain open and the reaction gasses 703 exit through an exchange chamber 702 or the gate valve 703 may be closed and a secondary exhaust 717 may be used. During the CVD or ALD process, a controller 719 (analog or digital) may be used to control the temperature in an oven or process chamber 701 and the flow of the gasses 703 through the process chamber 701. The flow rate, duration, sequence, and combination of the gasses 703 may be controlled with the same controller 719. For example, the controller 719 may be a Series CN8261 controller by Omega Engineering, Inc. capable of controlling an oven temperature with closed loop PID logic. And, for example, the gas flow controller 718 may be a P-Series mass flow controller by MKS Instruments, Inc. capable of flowing gasses with flow rates from 0.1 sccm to 5000 sccm.

A CVD system, such as described with respect to FIG. 7, that includes a CVD chamber and an additional process chamber, provides for additional processes that may be performed on the stack, in accordance with other embodiments of the invention. For example, the additional process chamber may be used for high temperature water vapor-based or oxygen-based purification of the CNTs grown in the stack to remove any defects in the CNTs and/or to remove amorphous carbon from the CNT films.

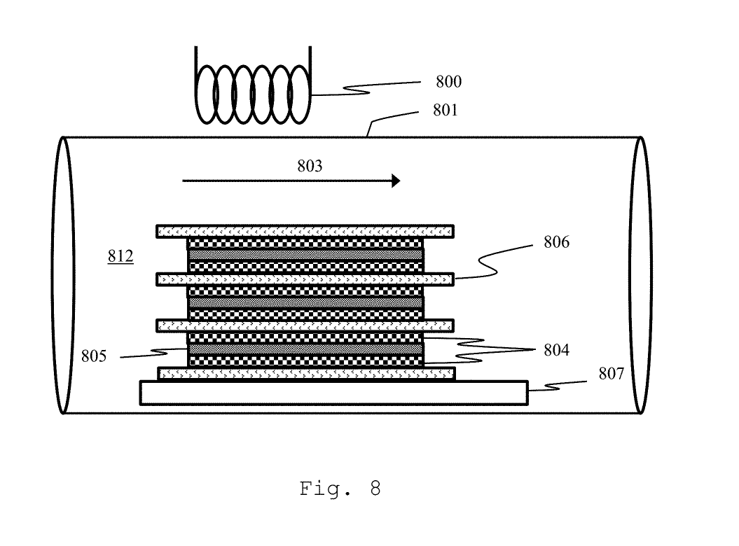

FIG. 8 schematically shows simultaneous growth of graphene 804 on both sides (top and bottom) of each of multiple stacked Cu or Ni foils 805 separated by gas permeable separators 806 that form a sample 812, in accordance with an embodiment of the invention. The gas permeable separators 806 enable the top and bottom sides of each of the Cu or Ni foils 805 to be exposed to the mixture of gasses 803 and the heat from a CVD heater 800, as described above. After the sample 812 is inserted inside a CVD tube chamber 801, a CVD reaction may commence. A typical CVD reaction for growth of the graphene 804 involves heating the tube 801 under an Argon and Hydrogen flow in a ratio of 1:1 until reaching a stable temperature of 1000 C or less, for example a temperature of 900 C, depending on type of foil material, such as Cu or Ni. Afterwards, a precursor gas 803, such as methane, is flowed in a ratio of 100:1 with respect to Argon. Other precursor gasses, such as ethylene or acetylene may also be used. Typical reaction times are 3 to 5 minutes. After this time period, the precursor flow is stopped and the sample 812 may be removed from the CVD chamber 801. In some embodiments, the sample 812, as for the sample 712 in FIG. 7, is removed from a hot zone (not shown in FIG. 8) of the CVD chamber 801 like the hot zone 714 into an exchange zone (not shown in FIG. 8) of the CVD chamber 801 like the exchange zone 715 where it may be cooled. Or the oven or chamber 801, like the oven 701, may be turned off, and the sample 812 and the oven 801, like the sample 712 and the oven 701, cooled together.

For the purpose of growing a hybrid graphene (G)-carbon nanotube (CNT) material, which is described in published PCT patent application (WO 2013/119295 A1), incorporated herein by reference in its entirety, the graphene-coated Cu or Ni foils are coated with a thin layer of a catalyst incorporating iron and alumina or aluminum to help aid the fabrication of CNTs. The catalyst layer may instead be cobalt or nickel. In this process of fabricating the hybrid G-CNT material, the CNTs will only grow on the areas where the catalyst is deposited. If the catalyst is deposited only on the top side of the graphene, the CVD process will produce growth of CNTs on the top side of the graphene. Depending on the CVD growth process, the grown CNTs may be single-walled CNTs, double-walled CNTs, multi-walled CNTs, or their combinations. Also, depending on the CVD growth process, the grown CNTs may be vertically aligned CNTs, bundles of CNTs grown together, or randomly aligned CNTs. The CNTs may be from a few microns to a few hundreds of microns in length, and their length may be controlled by the duration of the CVD process.

When a fiber filter separator is used in a CVD process traces of the separator fiber may be found mixed with the nanomaterial as a pollutant. Typically, traces of tens of quartz fibers per cm² of nanomaterial may be found after a quartz separator is removed. For many applications, such as the use of a CNT film as an anode in a lithium ion battery, the traces of quarts fiber are inert to the battery electrolyte and will not alter the performance of the battery. For other applications, such as the use of a graphene film as an anode in a lithium-ion battery or an electrode for a display apparatus, the traces of quartz fiber may be wiped off with the help of compressed dry nitrogen gas or by rinsing the foil with graphene in a liquid cleansing solution.

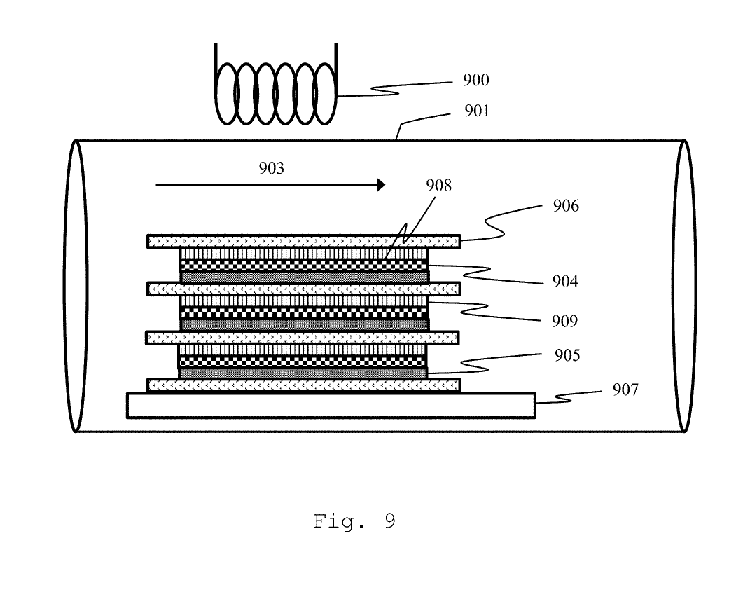

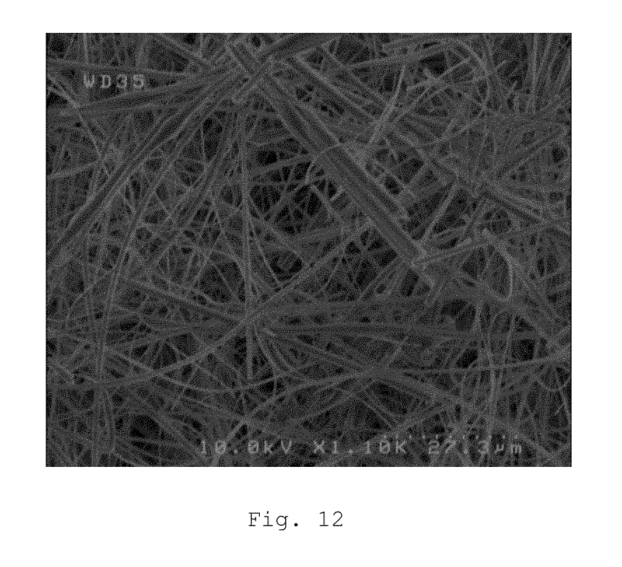

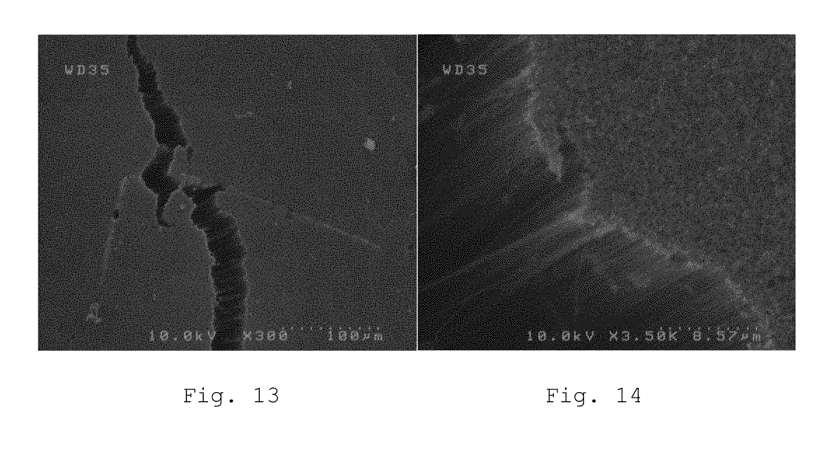

FIG. 9 schematically shows a system that enables simultaneous growth of CNTs 909 from graphene 904 coated with a CNT catalyst 908 on single sides (tops) of multiple stacked Cu or Ni foils 905 separated by gas permeable separators 906, in accordance with an embodiment of the invention. The gas permeable separators 906 enable the top side of each of the Cu or Ni foils 905 to be exposed to a mixture of gasses 903 inside a CVD chamber 901 and the heat from a CVD heater 900. FIGS. 13 and 14 (a close-up of FIG. 13) show micrographs of a vertically aligned CNT film that was grown on top of a graphene film that was already grown on a Ni foil substrate, in accordance with an embodiment of the invention. The CNTs were grown such that the Ni foil with graphene film was sandwiched between two gas permeable quartz fiber separators.

One advantage of using a gas permeable separator(s) is that it (they) increases (increase) the density of the CNT film in units of mg/cm² as compared to the density of a CNT film grown without the use of a gas permeable separator(s). The separator may slow down the flow of process gases near the CNT catalyst, such that slower gas flow may enable more catalytic particles to nucleate, resulting in the growth of a denser CNT film. In one example, the CNT density on a sample grown without the use of a gas permeable separator was less than 1 mg/cm² as opposed to a density between 1-2 mg/cm2 for a CNT film grown with a gas permeable separator. By using gas permeable separators, CNT films with densities of 4 mg/cm² or larger are possible.

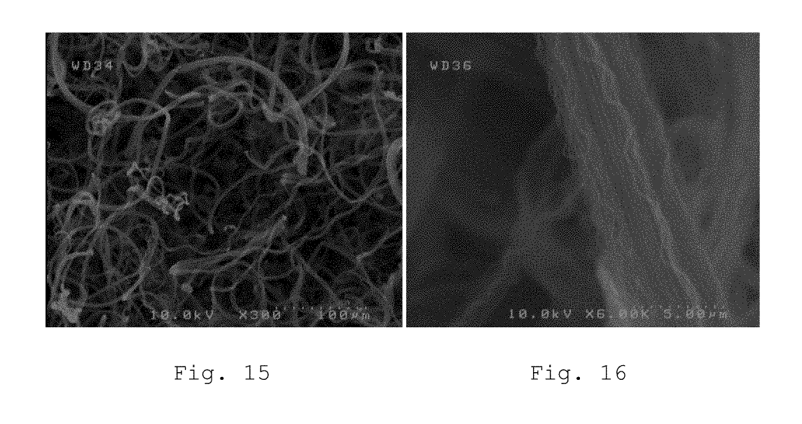

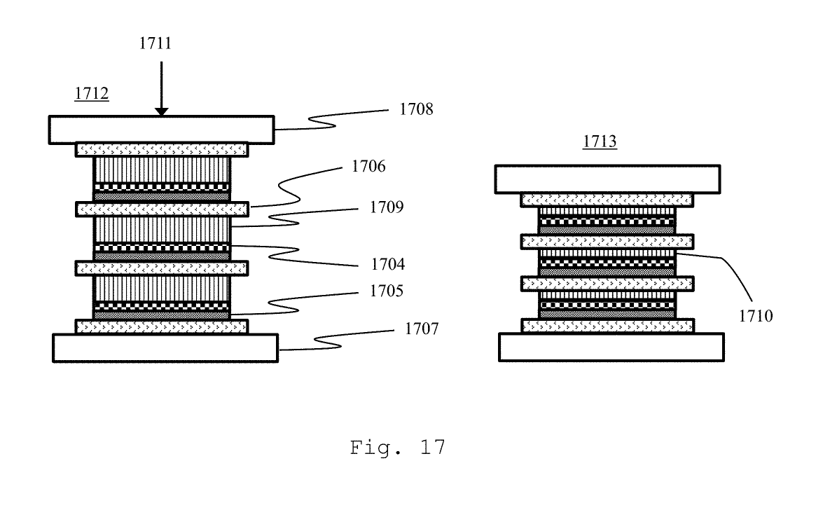

FIGS. 15 and 16 (a close-up of FIG. 15) show micrographs of a CNT film with bundled CNTs that was grown on top of a graphene film that was already grown on a Ni foil substrate, in accordance with an embodiment of the invention. The CNTs were grown such that the Ni foil with graphene film was sandwiched between two gas permeable quartz fiber separators. The thickness of the thin layer of catalyst incorporating iron and alumina or aluminum would also help to control the CNT density as well as the morphology of the CNT film, such as vertically aligned or bundled.

FIG. 10 schematically shows a system that enables simultaneous growth of CNTs 1009 on graphene 1004 coated with CNT catalyst 1008 on both sides (top and bottom) of multiple stacked Cu or Ni foils 1005 separated by gas permeable separators 1006, in accordance with an embodiment of the invention. The gas permeable separators 1006 enable the top and bottom sides of each of the Cu or Ni foils 1005 to be exposed to the mixture of gasses 1003 inside the CVD chamber 1001 and the heat from the CVD heater 1000. Depositing the catalyst 1008 on both the top and bottom sides of the graphene 1004 aids the CVD process to produce the growth of the CNTs 1009 on both the top and bottom sides of the graphene 1004.

The coating of the CNT catalyst on the graphene may be unpatterned or patterned. In unpatterned catalyst deposition, large continuous surfaces or the entire side of a sample are coated with the catalyst using one of the common deposition methods, which include thermal evaporation, e-beam or ion-beam evaporation, sputtering, CVD deposition, ALD deposition, wet chemical deposition, or wet electrochemical deposition. During a CVD process the CNTs will grow where the catalyst is available. In patterned deposition, the graphene is lithographically patterned on the entire side of the sample or on a section of the sample using standard lithography processes well known in the semiconductor industry arts. In patterned deposition, during a CVD process, the CNT film will grow only where the catalyst is available on the patterned graphene regions.

The graphene does not have to be grown by a CVD process, but instead may be deposited by submersion of graphene flakes in a solution that promotes the deposition of the graphene flakes on the Cu or Ni foils. The graphene may be a graphene oxide that is converted to graphene before or after the deposition on the foil. The graphene layers grown by CVD may be a single layer or a few layers of graphene, or they may be multilayers of graphene. In accordance with other embodiments, the graphene may also be substituted by graphite.

The CNT catalyst, nonlimiting examples of which include iron, cobalt, nickel and their alloys, aluminum and alumina, may be deposited on the foil(s) in the form of a thin film(s). Processes, such as thermal evaporation, e-beam evaporation, sputtering, and CVD deposition of organometallic precursors, may be used to produce the catalyst films, in accordance with embodiments of the invention. Other ways of depositing the CNT catalyst film(s) on the foil(s) include wet catalyst deposition, such as electrochemical deposition, drop casting, spin coating, doctor blade coating, dip coating, Langmuir-Blodgett coating, and spray coating, in accordance with other embodiments of the invention.

Other nanomaterials or structures, such as nanowires, may be grown or fabricated using the teachings described herein, in accordance with embodiments of the invention. Nonlimiting examples of such nanowires include silicon, germanium, ZnO, and TiO₂ nanowires.

The gas permeable separators described herein may be used for CVD growth of CNTs directly, without graphene or graphite, on substrates other than Cu and Ni foils, in accordance with embodiments of the invention. For example, the substrate may be a stainless steel foil coated with a CNT catalyst that enables CNTs to be grown on the surface of the stainless steel foil. Or the CNTs may be grown instead on stainless steel mesh, silicon, and silicon oxide wafers, to name a few common substrates on which CNTs are known to grow after the substrate is coated with a CNT catalyst.

After a single use in helping to grow nanomaterials, the quartz-based gas permeable separators will be slightly coated with carbon-based contamination, as is typical for any quartz-based tube or fixture used in a CVD or ALD process. Nevertheless, the gas permeable separators may be used multiple times without affecting the growth of the graphene or CNTs. This is because the quartz-based gas permeable separators may be cleaned easily by heating a stack of empty separators (i.e., with no foils in the stack) for 30 minutes in air at high temperature, such as 600 C to 900 C. Alternatively, the quartz-based gas permeable separators may be cleaned by soaking them in acid, such as HCl, for 1 hour or more, rinsing them with deionized (DI) water, and drying them in air at a lower temperature, such as 100 C to 200 C.

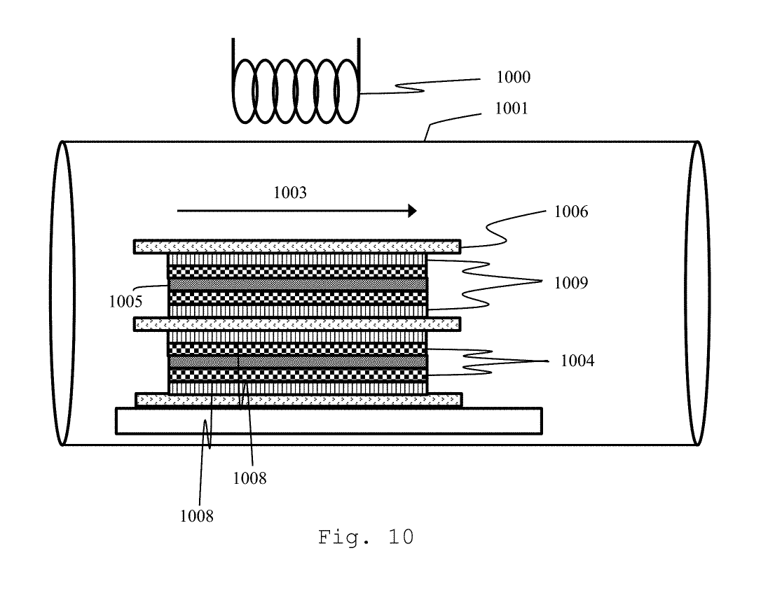

FIG. 11 schematically shows an end view of a single foil 1105 (e.g., a Cu or Ni foil) packaged with a single gas permeable separator 1106 as a rolled assembly 1107 forming a spiral or roll for insertion inside a tube chamber 1101, in accordance with an embodiment of the invention. This form of packaging or assembly 1107 is suitable for growth of graphene film on each side surface of the foil 1105. Another exemplary embodiment is a foil 1105 (e.g., a Ni foil) having graphene grown on it and covered with a CNT catalyst material that is packaged with a single gas permeable separator 1106 and rolled together as a rolled assembly forming a roll or spiral for insertion inside the tube chamber 1101. This form of packaging also uses the tube chamber 1101 more efficiently than a single strip of foil, and is advantageous when a dimension (e.g., the width) of the Cu or Ni foil is larger than the diameter of the CVD tube. As discussed above, the main limitation on the length of the roll is the length of the tube chamber. The main limitation on a diameter 1111 of the roll is an inner diameter 1108 of the tube chamber 1101, which limits how long the unfolded sheet width may be before being rolled up. This type of assembly is especially useful for extremely thin metal foils that may be rolled up with a very small gap 1110. For example, using a 0.38 mm thick gas permeable separator and 0.02 mm thick foil, the foil and separator assembly may be rolled up with a roll gap or roll pitch 1110 of 0.40 mm without compressing the separator, or the gap or pitch may be less than 0.40 mm if the separator is compressed by tightly rolling the foil and separator assembly. For example, with a 0.1 mm thick gas permeable separator and a 0.02 mm thick foil, the roll gap 1110 would be 0.12 mm without separator compression or less than 0.12 mm with separator compression, for example 10% less. Alternatively a stack of a first separator, a first foil, a second separator, a second foil, or more separators and foils, may be rolled forming a roll or spiral for insertion inside a tube chamber in accordance with an embodiment of the invention.

The gas permeable separator 1106 also would need to be flexible enough to be able to roll it. If the separator is not flexible or is rigid, only strips or pieces of the separator may be used to roll the thin foil, in accordance with embodiments of the invention. Without using a gas permeable separator(s) it would be very difficult to roll a thin metal foil into a spiral that has a small gap where the foil would not contact itself or has a uniform or constant gap over the diameter of the roll. In addition, a thin metal foil without separator support may not have enough mechanical stability to keep the gap between the rolled foil uniform or constant.

Considering the 0.38 mm thick gas permeable separator 1106 and 0.02 mm thick foil 1105 rolled assembly 1107 described above, for a tube furnace with 6 inches inner radius 1108, core 1104 with radius 1109 of 1 inch, determined by the minimum bend radius, and tube length that can fit 1 m long foil, the total width of the foil that can fit in the CVD or ALD system is 180 m, or 180 m² for 1 m long foil. The minimum bend radius is determined by the smallest bending of the foil and separator that does not alter the structure of the separator and does not produce stress in the foil that will cause a wrinkling of the nanomaterial after the roll is unwound, as would be understood by a person of ordinary skill in the art. The processing of such a large-sized foil width per single batch of a CVD or ALD process will result in a high volume manufacturing capability, producing, for example, the 180 m² of graphene on a foil in 3-5 minutes, and therefore will lower manufacturing costs for growing the nanomaterials per unit area. Prior art systems may not achieve such a large production capacity and avoid higher manufacturing costs.

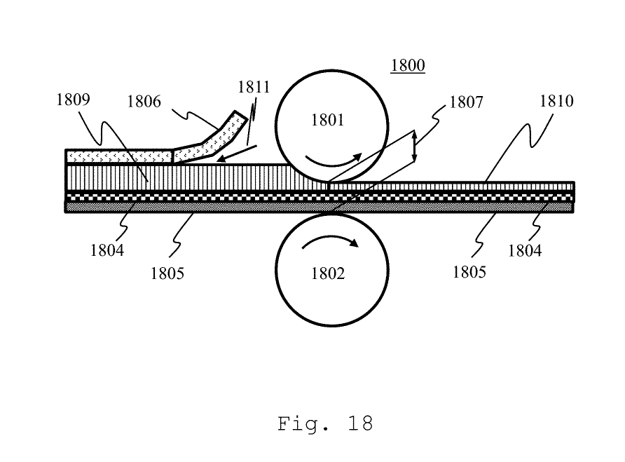

Although some of the discussion above relates to compression of the separators, the CNT films may also be compressed in a post growth process. Specifically, a stack of multiple foils and separators may be removed from the CVD or ALD chamber and the CNT film of each of the multiple-stacked foils may be simultaneously compressed to increase the volumetric density of the CNT film grown on each foil and in the stack as a group, in accordance with embodiments of the invention. In one exemplary embodiment shown in FIG. 17, a CNT film 1709 (shown on the left side of FIG. 17) of a grown thickness in a stack 1712 is compressed (the result of which is shown on the right side of FIG. 17) by 50× to increase its volumetric density to result in the CNT film 1710. FIG. 19 shows a pair of micrographs of such a CNT film before (left) and after (right) the compression.

Compression of the nanomaterial 1709 may be performed directly, after the stack 1712 of foils 1705 and separators 1706 is removed from the CVD or ALD chamber, with the help of rigid and smooth (e.g., stainless steel or Teflon) plates 1707 and 1708 being moved toward each other under the urging of a press or clamping mechanism (not shown in FIG. 17), such as a hydraulic press, in accordance with an embodiment of the invention. If the gas permeable separators 1706 are flexible they will also compress in addition to the nanomaterials 1709. On the other hand, if the gas permeable separators 1706 are rigid or stiff the nanomaterials 1709 will be compressed but not the separators 1706. Compressed stack 1713 (formed by compression of the stack 1712) with the compressed CNTs 1710 is thinner than the uncompressed stack 1712 by the amount of compression times the number of elements compressed (i.e., by the number of nanomaterial films 1709 and separators 1706, if flexible, that are compressed).

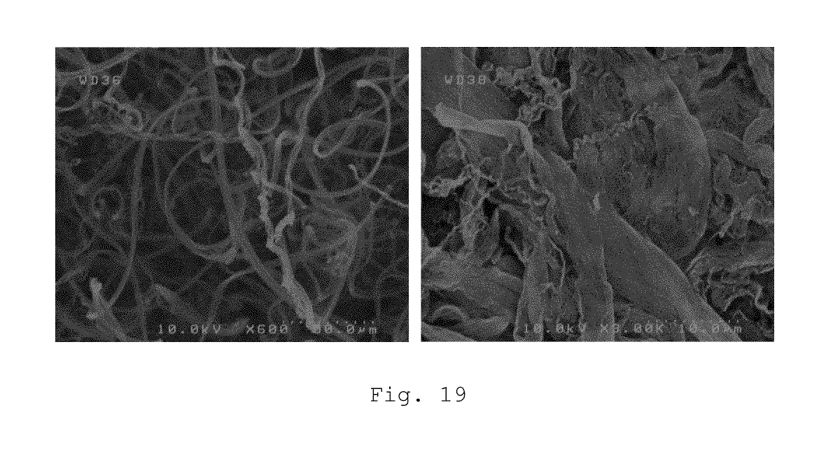

FIG. 18 schematically shows a roller system 1800 used to peel off a separator 1806 with the help of a blade or a mechanical lift arm 1811 and compress an already grown CNT film 1809, which was grown on top of a foil 1805 and graphene film 1804 that is coated with a CNT catalyst, to form a compressed CNT film 1810, in accordance with an embodiment of the invention. The graphene film 1804 will not be compressed because its thickness is only a few atoms thick, and therefore it is not easily compressible. The resulting thickness of the compressed CNT film 1810 may be adjusted by controlling a gap 1807 between opposed rollers 1801 and 1802 as the CNT film 1809 enters into and passes through this gap (manually or automatically by a driving mechanism not shown in FIG. 18) as the opposed rollers 1801 and 1802 turn. For example, an approximately 100 micron thick CNT film may be compressed to an approximately 10 micron thick CNT film by setting the gap between the rollers to be 10 microns with a tolerance of 10%.

Additional processes may be performed on a compressed stack, such as high temperature water vapor-based or oxygen-based purification of the CNTs in the stack for the purpose of removing any defects on the CNTs and/or removing amorphous carbon from the CNT film. Additional CVD coating or similar processes may also be performed on the stack after it is compressed. In addition, the stack of compressed CNTs on the foils may also be submerged into liquids for additional processing, such as drop-cast deposition or electrodeposition of reduced metal oxides for Li-ion battery electrodes, or pre-lithiation of an anode for Li-ion battery electrodes.

Embodiments of the invention have applications, including but not limited to, high volume production using CVD tools in the semiconductor industry, and high volume production of nanomaterials, such as graphene and carbon nanotubes for batteries, such as Li-ion batteries, and for supercapacitors, structural materials, displays and touch screens, biological scaffolds, and sensors.

The specific embodiments described above are merely exemplary, and it should be understood that these embodiments may be susceptible to various modifications and alternative forms. It should be further understood that the claims are not intended to be limited to the particular embodiments or forms disclosed, but rather to cover all modifications, equivalents, and alternatives falling within the spirit and scope of this disclosure.

1. An apparatus for use in making a nanomaterial in a gas deposition process, comprising:
one or more foils; and
one or more gas permeable separators, each gas permeable separator placed in physical contact with one or at most two of the one or more foils.

2. The apparatus of claim 1, wherein the apparatus is for use in growing the nanomaterial on the one or more foils.

3. The apparatus of claim 1, wherein the nanomaterial comprises graphene.

4. The apparatus of claim 1, wherein the nanomaterial comprises carbon nanotubes (CNTS).

5. The apparatus of claim 1, wherein the nanomaterial comprises graphene and carbon nanotubes (CNTS).

6. The apparatus of claim 1, wherein the nanomaterial comprises one of graphite, graphene flakes, graphene oxide, reduced graphene oxide, and graphene nanoribbons.

7. The apparatus of claim 1, wherein the one or more foils already comprise a second nanomaterial grown thereon.

8. The apparatus of claim 1, wherein one foil is rolled with one gas permeable separator.

9. The apparatus of claim 1, wherein the one or more foils are stacked with the one or more gas permeable separators.

10. The apparatus of claim 1, wherein the gas deposition process is chemical vapor deposition (CVD).

11. The apparatus of claim 1, wherein the gas deposition process is atomic layer deposition (ALD).

12. The apparatus of claim 1, wherein the one or more gas permeable separators comprise quartz fiber filter.

13. The apparatus of claim 1, wherein the one or more gas permeable separators are flexible.

14. The apparatus of claim 1, wherein the one or more gas permeable separators have a thickness of 0.38 mm to 1.0 mm.

15. The apparatus of claim 1, wherein the one or more gas permeable separators comprise pores having a pore size in the range 0.1 microns to 10.0 microns.

16. An apparatus for use in making a nanomaterial in a gas deposition process, comprising:
a foil; and
a gas permeable separator placed in physical contact with and rolled together with the foil.

17. The apparatus of claim 16, further comprising a foil pitch of 0.40 mm or less.

18. The apparatus of claim 16, wherein the rolled foil and the gas permeable separator are rolled such that the gas permeable separator is compressed.

19. An apparatus for use in making a nanomaterial in a gas deposition process, comprising:
a metal foam configured as a substrate and a gas permeable separator; and
the metal foam is rolled upon itself such that adjacent rolled portions of the metal foam physically touch each other.
